(19) United States
(12) Patent Application Publication
(10) Pub. No.: US 2012/0085391 A1
(43) Pub. Date: Apr. 12, 2012

(54) STRUCTURE AND METHOD FOR MOUNTING A PHOTOVOLTAIC MATERIAL

(76) Inventors: Uday Varde, West Bloomfield, MI (US); Jonathan Call, Royal Oak, MI (US)

(21) Appl. No.: 12/898,816

(22) Filed: Oct. 6, 2010

(51) Int. Cl. H01L 31/048; H01L 31/18; E04D 13/18

(52) U.S. Cl. 136/251; 29/428

(57) ABSTRACT

A photovoltaic device is adhesively mounted to a support structure such as a roofing member or building panel by the use of a body of foamed adhesive. The foamed adhesive is resilient and accommodates differences in the thermal expansion and contraction of materials comprising the photovoltaic device and the structure upon which it is mounted and thereby prevents delamination and other stress-related damage to the photovoltaic installation. The adhesive may comprise a contact adhesive, a hot melt adhesive, or a curable adhesive. Further disclosed are methods for affixing photovoltaic systems to building structures and the like through the use of foamed adhesives.

### FIELD OF THE INVENTION

This invention relates, generally, to photovoltaic devices. More particularly, the invention relates to a power generating photovoltaic member which is capable of being adhesively affixed to a building structure or the like and which accommodates the differential thermal expansion and contraction of the building structure and the photovoltaic material.

### BACKGROUND OF THE INVENTION

The use of photovoltaic devices as large-scale sources of electrical power is increasing owing to improvements in the efficiency and power/weight ratio of such devices, as well as to production efficiencies which have lowered their costs. Photovoltaic installations typically occupy relatively large areas; hence, roofs, upper story walls, and other unused areas of building structures with exposure to solar irradiance, are often employed to support photovoltaic power installations. Any such installation should be resistant to environmental conditions including wind loading, temperature variations, and the like. Additionally, the installation should be light in weight and easy to install and remove. In a number of instances, photovoltaic devices are mounted onto roofing membranes, wall structures, and the like through the use of adhesive materials, and such installations are shown in U.S. Pat. Nos. 6,729,081 and 6,553,729, the disclosures of which are incorporated herein by reference.

It has been found that in those instances where relatively large area photovoltaic members are mounted onto building structures, even small mismatches in the thermal expansion coefficients of the photovoltaic material and the surface upon which that material is mounted can result in the creation of relatively large stresses which can delaminate cells, cause buckling within or between cells, and/or short the photovoltaic layers or otherwise damage the photovoltaic installation. The present invention has recognized a source of such stresses and, as will be described in detail hereinbelow, has developed a solution to this problem based upon the use of foamed adhesive materials which are capable of accommodating differential thermal expansions while still retaining the integrity of the adhesive bond. Details of the invention will be apparent from the drawings, discussion, and description which follow.

### BRIEF DESCRIPTION OF THE INVENTION

Disclosed is an adhesively affixable photovoltaic member which includes a photovoltaic device having a body of photovoltaic semiconductor material winch operates to absorb incident photons and generate an electrical current in response thereto. The photovoltaic device further includes a substrate having the body of photovoltaic semiconductor material supported on a first surface of the substrate. The photovoltaic member further includes a body of a foamed adhesive disposed on a second surface of the substrate opposite the first surface. The foamed adhesive is operative to bond the photovoltaic device to a support member while accommodating the differential thermal expansion of the photovoltaic device and the support member. The foamed adhesive may include but is not limited to; a contact adhesive, a thermoplastic adhesive, a thermoset adhesive or a hot melt adhesive that can be thermoplastic or thermoset. In specific instances, the foamed adhesive has a void volume in the range of 5-80 percent, and in specific instances 40-50 percent. The foam may have an at least partially closed cellular structure, and the voids may be formed by gas bubbles or hollow microspheres. In some instances, the body of adhesive includes a layer of release material affixed to it.

Also disclosed is a photovoltaic installation in which a photovoltaic device is affixed to a support member such as a roof structure through the use of a foamed adhesive. Further disclosed is a method for affixing photovoltaic devices to support structures through the use of a foamed adhesive.

### BRIEF DESCRIPTION OF THE DRAWINGS

FIG. 1 is a cross-sectional view of a portion of a first embodiment of an adhesively affixable photovoltaic member; and

FIG. 2 is a cross-sectional view of a portion of another embodiment of an adhesively affixable photovoltaic member.

### DETAILED DESCRIPTION OF THE INVENTION

In general, the present invention comprises the use of a foamed adhesive material to bond photovoltaic devices to support structures such as roofing membranes, building panels, and the like. The foamed adhesive provides elasticity to the bond which allows the installation to accommodate stresses and strains resultant from the differential thermal expansion and contraction of the various components of the photovoltaic material and the underlying support structure to which it is bonded. This invention may be implemented in a variety of embodiments utilizing various foamed adhesives and various configurations of photovoltaic device. The invention will be explained with reference to some very specific embodiments, and it is to be understood that these embodiments are illustrative of the general principle, and the invention may be otherwise implemented.

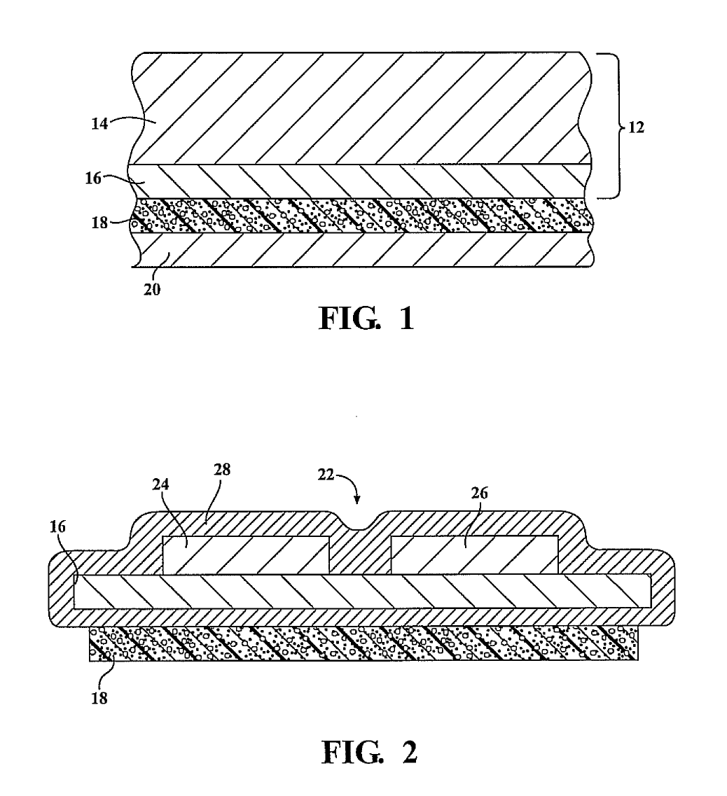

Referring now to FIG. 1, there is shown a cross-sectional view of a photovoltaic member 10 in accord with the present invention. The member 10 includes a photovoltaic device shown generally at reference numeral 12. The photovoltaic device includes a photovoltaic semiconductor body 14 which includes one or more semiconductor layers and which operates to absorb incident photons and generate an electrical current in response thereto. In one specific embodiment of the present invention, the photovoltaic body 14 includes a plurality of thin film semiconductor layers such as amorphous and/or microcrystalline layers of alloys of hydrogenated silicon and/or germanium. However, it is to be understood that other semiconductor materials such as cadmium telluride, cadmium sulfide, and the like may be also utilized in the practice of the present invention, as may be single crystal and polycrystalline materials. As is known in the art, the photovoltaic body 14 may include current collecting electrode structures, protective layers, current buffer layers, and the like. As is further shown in FIG. 1, the photovoltaic device 12 includes a substrate material 16 having the body of photovoltaic semiconductor material 14 supported on a first face thereof. As shown in FIG. 1, this body 14 is supported directly upon the first face of the substrate 16, although it is to be understood that additional layers such as reflective layers, optical tuning layers, texture layers, and the like may be incorporated either into the substrate or be disposed between the substrate 16 and the semiconductor body 14. In some specific instances, the substrate 16 may be a metallic substrate which may additionally function as a component of the bottom electrode of the photovoltaic device. In other instances, the substrate 16 may comprise a layer of polymeric material.

As further shown in FIG. 1, a layer of a foamed adhesive material 18 is supported on a second face of the substrate 16. In this instance, the adhesive material 18 is supported directly on the second face of the substrate 16, although it is to be understood that additional layers such as reinforcement layers and the like may be interposed therebetween.

The foamed adhesive 18 is characterized in that it includes a plurality of voids, also referred to as cells, defined therein. In particular instances, the combined volume of these voids, referred to as the “void volume” of the adhesive, will be in the range of 5-80 percent. That is to say, of the total volume of the adhesive, 5-80 percent of the volume will be constituted by the voids. In specific instances, void volumes of 40-50 percent are utilized in the practice of the present invention. It has been found that the presence of the voids in the adhesive enhances the resilience and elongation of the adhesive under stress and this resiliency allows the foamed adhesive to accommodate dimensional discrepancies between the photovoltaic device and an underlying substrate to which it is bonded. In addition to providing accommodation for the thermal expansion and contraction, the foamed adhesive layer also significantly decreases the weight of the adhesive material without decreasing the area of contact between the adhesive and the surface to which it is affixed; therefore, the foamed adhesive allows for the use of a thicker adhesive body and/or a decreased amount of adhesive as compared to systems utilizing nonfoamed adhesives.

In particular instances, the voids are formed in the adhesive by bubbles of gas dispersed therein. There are a number of gases which may be utilized to prepare the foamed adhesives, and such gases can include air, nitrogen, argon, xenon, or other noble gases as well as hydrocarbons or halocarbons such as chlorocarbons, fluorocarbons and the like. In some instances the foaming may be accomplished by the use of chemical compounds which decompose to release a gas, typically nitrogen. Such agents include Azobisformamide type compounds and the like. In other instances, the foam structure may be provided by dispersing hollow microspheres such as glass or polymeric microspheres in the adhesive. Such microspheres are known and readily available to those of skill in the art.

Various adhesives may be used to prepare the foamed adhesive layer, and such adhesives include acrylics, urethanes, silicones, elastomeric compounds such as EP rubbers, butyl rubbers, and the like. Photosensitive adhesives such as UV tackifiable PSA adhesives comprise polymeric materials which can be applied to a surface as a relatively low viscosity resin and subsequently tackified by exposure to ultraviolet radiation so as to convert them to a contact adhesive material; and, such materials may also be used as a basis for the foamed adhesive.

As is shown in FIG. 1, a release layer 20 may be applied to the adhesive layer 18 so as to protect it during shipping and handling. This release layer 20 may comprise a layer of paper or polymeric material coated with a release coating of a silicone or the like and its inclusion has been found particularly advantageous in those instances where the adhesive layer 18 is a contact adhesive.

In some instances, the present invention may be implemented utilizing curable adhesives. Such adhesives include chemically curable adhesives as well as optically curable and thermally curable adhesives. In yet other instances, the adhesive may comprise a hot melt adhesive. Use of curable and hot melt adhesives may confer particular advantages in those instances where the photovoltaic members are being affixed to support structures in a manufacturing situation or in a high volume onsite installation system. Contact adhesives will often be found to be advantageously employed in those situations in which worksite application or consumer application of the devices is anticipated.

Referring now to FIG. 2, there is shown another embodiment 22 of photovoltaic member in accord with the principles of the present invention. In this embodiment, the photovoltaic device portion is comprised of a substrate 16 which can be generally similar to the previously described substrate and is further comprised of two photovoltaic bodies 24 and 26 disposed on the substrate 16. In this instance, the photovoltaic bodies 24 and 26 may each comprise discrete photovoltaic cells, or arrays of such cells. As such, each body 24, 26 will include semiconductor layers, electrodes, and substrates; and in particular instances, the individual photovoltaic bodies 24 and 26 may be interconnected in a series or parallel relationship to form a module as is known in the art. In the FIG. 2 embodiment, the substrate 16 and photovoltaic bodies 24 and 26 are encapsulated in an encapsulant material 28 which, in this embodiment, covers the entirety of the bodies 24 and 26 as well as the substrate 16. In other embodiments, the encapsulant may cover only the photovoltaic bodies 24 and 26 and upper surface of the substrate 16. As is known in the art, such encapsulants will typically comprise polymeric materials and will be light transparent at least with regard to that portion thereof which covers the light-incident side of the photovoltaic bodies. In the FIG. 2 embodiment, a layer of foamed adhesive 18 is disposed so as to be supported by the second surface of the substrate 16, which in this case further includes the intervening portion of the encapsulant 28. The FIG. 2 embodiment, like the FIG. 1 embodiment, may also include an optional release layer, although such layer is not shown in FIG. 2.

Various techniques may be employed for preparing the foamed adhesive layers. As described above, foaming may be accomplished by introducing a gas into the adhesive, and systems for doing so are commercially available from a number of suppliers including the Nordson Corporation of Duluth, Ga. In other instances, foaming may be accomplished by incorporating a chemical foaming agent into the adhesive mixture. Such foaming agents include chemically reactive compounds such as azides which decompose to release nitrogen, as well as vaporizable agents such as hydrocarbon or chlorofluorocarbon blowing agents which volatilize to produce bubbles in the adhesive. As previously noted, foaming may also be accomplished by mixing hollow microspheres of glass or polymer into the adhesive to create voids. As is known in the art, the foaming of the adhesive may produce an open-cell structure in which the voids are in communication with one another. The foaming may alternatively produce a closed-cell structure in which the interior of each of the voids is essentially separate from the others. In yet other instances, a mixed open-cell/closed-cell structure may be produced. All of such structures may be used in the practice of the present invention. In general, open cell structures have greater elasticity than do closed cell structures, while closed cell structures are less permeable to moisture than are open cell structures. Thus, by controlling the ratio of closed cells to open cells in the adhesive structure, properties of the adhesive may be advantageously controlled. In roofing installations and other situations where good moisture resistance is required, the closed cell void volume of the foam should be at least 10%; however, in order to provide sufficient elasticity to the foam, the open cell void volume should be at least 30%. In a typical installation, where moisture resistance is required, the closed cell void volume of the foam will be in the range of 10% to 40%, and in specific instances, the closed cell void volume will be in the range of 10% to 25%.

In particular instances, the foamed adhesive may be directly applied to the photovoltaic structure either at the time of fabrication, or at the time the photovoltaic material is to be adhered to the support structure. In other instances, the foamed adhesive may be cast into a sheet member that is further processed and then adhered to the photovoltaic device and/or support structure. In yet other instances, the adhesive may be applied to the support structure and the photovoltaic device placed thereupon. All of such modes of application are contemplated within the scope of this disclosure. Various techniques may be employed for coating the adhesive. In some instances, a single apparatus may be used for foaming and dispensing the adhesive. In other instances, the adhesive may first be foamed, and then coated; while in yet other instances, foaming may be accomplished after coating, as for example by the use of foaming agents.

The thickness of the adhesive layer will depend upon the nature of the adhesive as well as the size, weight, and orientation of the photovoltaic device. However, in typical installations, the adhesive layer will have a thickness of at least 0.5 millimeters, and in more particular instances a thickness of approximately 1 millimeter or more. While thinner layers may be employed, the thickness should be selected such that sufficient flexibility and resilience will be achieved at the adhesive joint so as to accommodate differential expansion of the materials. While foamed adhesives are known in the art, the advantages and benefits dependent upon their use in connection with the installation of large area photovoltaic power systems has not been heretofore appreciated.

The foregoing describes some specific embodiments of the present invention. Yet other embodiments, modifications, and variations will be apparent to those of skill in the art in view of the teaching presented herein, and all of such embodiments, modifications, and variations are within the scope of the present invention. It is the following claims, including all equivalents, which define the scope of the invention.

1. An adhesively affixable photovoltaic member comprising:
a photovoltaic device including a body of a photovoltaic semiconductor material which operates to absorb incident photons and generate an electrical current in response thereto, said photovoltaic device further including a substrate having said body of photovoltaic semiconductor material supported upon a first face thereat and
a body of a foamed adhesive supported on a second face of said substrate opposite said first face; wherein said foamed adhesive is operative to bond said photovoltaic device to a support member while accommodating the differential thermal expansion of said photovoltaic device and said support member.

2. The photovoltaic member of claim 1, wherein said foamed adhesive is a contact adhesive.

3. The photovoltaic member of claim 1, wherein said foamed adhesive is a curable adhesive.

4. The photovoltaic member of claim 1, wherein said adhesive is a hot melt adhesive.

5. The photovoltaic member of claim 1, further including a removable body of a release material adhered to said adhesive layer.

6. The photovoltaic member of claim 1, wherein the void volume of said foamed adhesive is in the range of 5-80 percent.

7. The photovoltaic member of claim 6, wherein said void volume is in the range of 40-50 percent.

8. The photovoltaic member of claim 1, wherein said foamed adhesive has an at least partially closed cellular structure.

9. The photovoltaic member of claim 8, wherein foamed adhesive has a partially closed cellular structure in which the void volume of the closed cells is in the range of 10% to 40%

10. The photovoltaic member of claim 1, wherein the foamed structure of said adhesive is provided by a plurality of gas bubbles dispersed therein.

11. The photovoltaic member of claim 10, wherein said gas bubbles comprise a gas selected from the group consisting of: air, nitrogen, argon, helium, a fluorocarbon, and combinations thereof.

12. The photovoltaic member of claim 1, wherein the foamed structure of said adhesive is defined by a plurality of hollow microspheres dispersed therein.

13. The photovoltaic member of claim 1, wherein said body of foamed adhesive has a thickness of at least 0.5 millimeters.

14. The photovoltaic member of claim 1, wherein said photovoltaic device comprises a body of a thin film semiconductor material and said substrate comprises a metal.

15. The photovoltaic member of claim 1, wherein said photovoltaic device includes a transparent encapsulant layer disposed on a light-incident side of said photovoltaic device.

16. The photovoltaic member of claim 1, wherein said substrate includes a layer of an encapsulant material covering the second face thereof, and wherein said body of foamed adhesive is disposed atop said layer of encapsulant material.

17. A photovoltaic installation comprising:
a support member;
at least one photovoltaic device; and
a foamed adhesive which adhesively affixes said at least one photovoltaic device to said support member.

18. The photovoltaic installation of claim 17, wherein said support member is a building structure.

19. The photovoltaic installation of claim 17, wherein said support member is a roofing membrane.

20. A method for affixing a photovoltaic device to a support member, said method comprising adhesively affixing said photovoltaic device to said support member with a body of a foamed adhesive.
